(19) United States
(12) Patent Application Publication
(10) Pub. No.: US 2022/0293335 A1
(43) Pub. Date: Sep. 15, 2022

(54) METALLIC MAGNETIC MATERIAL WITH CONTROLLED FRAGMENT SIZE

(71) Applicant: 3M INNOVATIVE PROPERTIES COMPANY, St. Paul, MN (US)

(72) Inventors: Thomas J. Miller, Woodbury, MN (US); Sergei A. Manuilov, Bayport, MN (US)

(21) Appl. No.: 17/754,155

(22) PCT Filed: Sep. 28, 2020
(86) PCT No.: PCT/IB2020/059060

§ 371 Date: Mar. 25, 2022

Related U.S. Application Data
(60) Provisional application No. 62/908,337, filed on Sep. 30, 2019.

(51) Int. Cl. H01F 27/36; H01F 1/153

(52) U.S. Cl. CPC H01F 27/366; H01F 1/15333; H01F 1/15358

(57) ABSTRACT

An article includes one or more magnetic isolators. Each magnetic isolator comprises a layer of fragmented magnetic metallic material adhered to a substrate. The fragments of the magnetic metallic material are separated by spaces and arranged in a non-random pattern. The layer of fragmented magnetic metallic material has a thickness, t, greater than 1 μm and the spaces have an average width of less than 0.5t.

### TECHNICAL FIELD

This disclosure relates generally to magnetic isolators and to related devices and methods.

### BACKGROUND

The emergence and evolution of wearable electronic systems, such as smart phones, has led to technological advances in high-efficiency power storage, power conversion, and power transfer. Power transfer applications require high-performance magnetic materials for functions such as inductive coupling and electromagnetic interference shielding of the stray radio frequency power from rest of the system.

Inductive coupling facilitates the near field wireless transfer of electrical energy between two electrical coils. Inductive coupling is widely used in wireless charging systems. In this approach a transmitter coil in one device transmits electric power across a short distance to a receiver coil in other device. The inductive coupling between the coils can be enhanced by using high permeability magnetic materials.

### BRIEF SUMMARY

Some embodiments are directed to an article that includes one or more magnetic isolators. Each magnetic isolator comprises a layer of fragmented magnetic metallic material adhered to a substrate. The fragments of the magnetic metallic material are separated by spaces and arranged in a non-random pattern. The layer of fragmented magnetic metallic material has a thickness, t, greater than 1 μm and the spaces have an average width of less than 0.5 t.

According to some embodiments a device includes a material that is magnetically lossy when exposed to an electromagnetic signal. The device includes an antenna configured to transmit or receive the electromagnetic signal. A magnetic isolator is disposed between the antenna and the magnetically lossy material. Each magnetic isolator includes a layer of fragmented magnetic metallic material adhered to a substrate. The layer of the magnetic metallic material has a thickness, t, greater than 1 μm. Spaces that separate the fragments of the magnetic metallic material have an average width of less than 0.5 t and are arranged in a non-random pattern.

Some embodiments are directed to a method of making a magnetic isolator. A layer of magnetic metallic material is fractured into fragments arranged in a non-random pattern with spaces separating the fragments. The layer of the magnetic metallic material has a thickness, t, greater than 1 μm and the spaces separating the fragments having an average width of less than 0.5 t.

### BRIEF DESCRIPTION OF DRAWINGS

FIG. 1A is a plan view illustrating the structure of a magnetic isolator in accordance with some embodiments;

FIG. 1B is a cross sectional view of the magnetic isolator of FIG. 1A;

FIG. 1C shows a close up of a portion of the magnetic isolator of FIG. 1A;

FIG. 1D shows a close-up cross sectional view of crack that separates fragments of magnetic material of the magnetic isolator of FIG. 1A.

FIG. 2 is a plan view of a magnetic isolator having fragments separated by spaces wherein the fragments are arranged in a non-repeating pattern in accordance with some embodiments;

FIG. 3 is a plan view of a magnetic isolator having rectangular fragments arranged in a one dimensional repeating pattern in accordance with some embodiments;

FIG. 4 is a plan view of a magnetic isolator having square fragments arranged in a two dimensional array in accordance with some embodiments;

FIG. 5 is a plan view of a magnetic isolator having triangular fragments arranged in a radial pattern in accordance with some embodiments;

FIG. 6 is a plan view of a magnetic isolator having fragments that form concentric squares in accordance with some embodiments;

FIG. 7 is a plan view of a magnetic isolator having fragments that form concentric circles in accordance with some embodiments;

FIG. 8A is a diagram illustrating a cross sectional view of stacked magnetic isolators in accordance with some embodiments;

FIG. 8B shows the magnetic isolators of FIG. 8A in an exploded view.

FIGS. 9A through 9C are diagrams that illustrate a process for making a magnetic isolator in accordance with embodiments discussed herein;

FIG. 10 is a flow diagram that illustrates a process of making an article comprising one or more magnetic isolators in accordance with some embodiments;

FIGS. 11A through 11E illustrate a process of cracking a magnetic metallic material to achieve a non-random pattern of fragments in accordance with some embodiments;

FIG. 12 is a block diagram of a system that may incorporate one or more magnetic isolators as discussed herein to facilitate wireless battery charging or other processes in accordance with some embodiments;

FIG. 13 is a cross sectional diagram a cross section of an antenna wire illustrating shaping of magnetic flux lines in the vicinity of the receive or transmit antenna coils;

FIGS. 14 and 15 show plan views of magnetic isolators with coils arranged relative to the fragments of the magnetic isolators in accordance with some embodiments;

FIG. 16 is a graph showing measured values of real permeability as a function of fragment dimension;

FIG. 17 is a graph showing measured values of the ferromagnetic resonance frequency (f(FMR)) as a function of fragment dimension measured from samples;

FIG. 18 is a graph showing resistivity values (averaged over 4 samples each) with respect to compression factor for a magnetic isolator;

FIG. 19 illustrates a sample having the major axis of fragments arranged parallel to the outer edges of the square sheet of isolator material;

FIG. 20 illustrates a sample having the major axis of fragments arranged perpendicular to the outer edges of the square sheet of isolator material;

FIG. 21 is a diagram of a stack used to test the samples of FIGS. 19 and 20;

FIG. 22 provides graphs of the power transfer efficiency (power received/power transmitted (Prx/Ptx)) with respect to the received power, RX, for the samples of FIGS. 19 and 20;

FIG. 23 illustrates a sample having linear, or one-dimensional cracking used to measure magnetic permeability; and

FIG. 24 is a graph that shows the parallel and perpendicular magnetic permeability of the sample of FIG. 23.

The figures are not necessarily to scale. Like numbers used in the figures refer to like components. However, it will be understood that the use of a number to refer to a component in a given figure is not intended to limit the component in another figure labeled with the same number.

### DETAILED DESCRIPTION OF ILLUSTRATIVE EMBODIMENTS

This disclosure relates to magnetic isolator films and to methods of making and using magnetic isolator films. Magnetic isolators, also known as flux field directional materials, are thin sheets of magnetically soft material used to help couple a transmitted magnetic field to a receiver coil to increase power transfer efficiency. They are placed on the opposite side of the receiver coil from the transmitter coil to isolate any nearby magnetically lossy materials from the transmitted magnetic field. Magnetic nanocrystalline ribbon (NCR) is commonly used as the magnetically soft material in such isolators. Magnetic isolator films such as those described herein have application in wireless charging of batteries that power electronic devices, such as cellular telephones. The magnetic isolator films can serve to guide magnetic fields during wireless charging, to shield the battery and/or other electronic device components from electromagnetic fields, to reduce eddy currents induced by magnetic fields, and/or to enhance transfer efficiency and/or Q factor of wireless charging systems, for example.

Magnetic metallic NCR can be used in magnetic isolators and is generally fractured, or cracked, to reduce conductivity, which reduces eddy current losses in the material. Another generally positive effect of cracking is that it increases the ferromagnetic resonance frequency, f(FMR), which is the frequency that corresponds to a maximum in the imaginary component of the magnetic permeability. However, cracking NCR also decreases its magnetic permeability, which is a measure of its capacity to carry magnetic flux. The tradeoff between these values needs to be balanced for a given application.

The value of these quantities (permeability, f(FMR) and conductivity) has been shown herein to correlate with the fragment size of the cracked ribbon. According to the disclosed embodiments, controlling the fragment size through a controlled cracking process allows particular values of permeability, conductivity and f(FMR), within ranges to be achieved for a given annealed magnetic material. In addition to the ability to “dial in” these values, the disclosed approaches also reduce the variation of these values within a sample, and from sample to sample. The approaches discussed below provide some control of the values of permeability, FMR frequency, and conductivity of magnetic isolator films. Additionally, the approaches provide for control of the distribution of values of these parameters such that the spatial variation in the parameter is reduced.

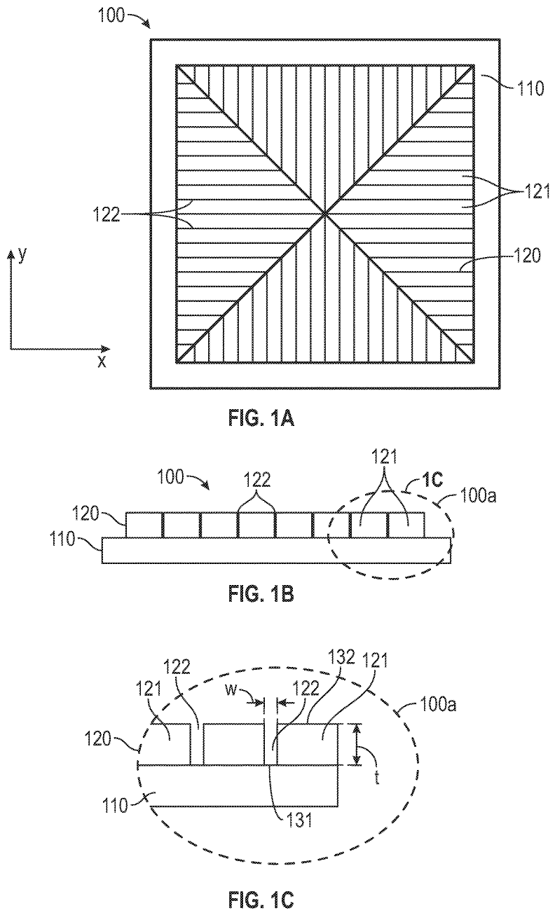

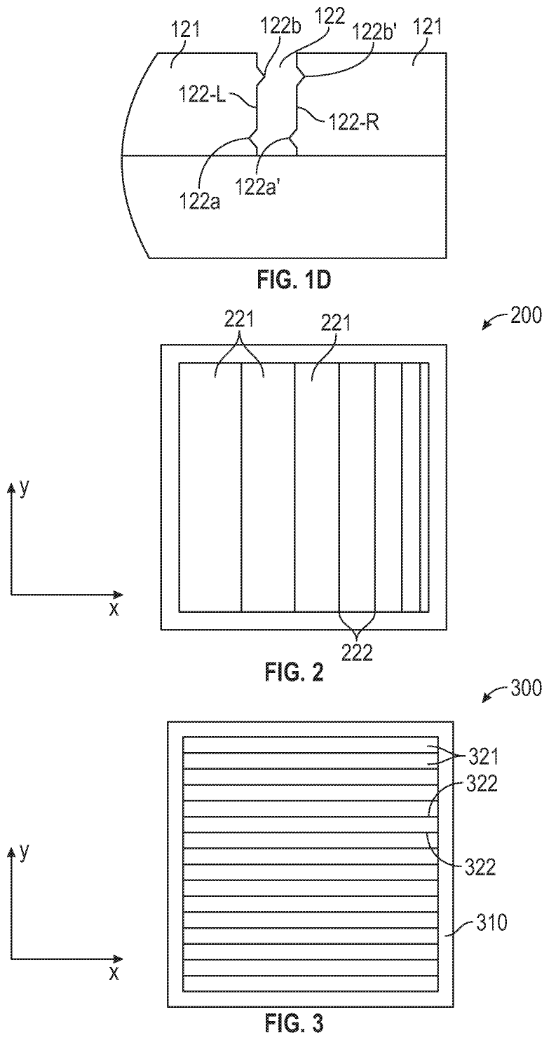

FIG. 1A is a plan view and FIG. 1B is a cross sectional view illustrating the structure of a magnetic isolator 100 in accordance with some embodiments. The magnetic isolator 100 includes a substrate 110 having a layer 120 of fragmented magnetic metallic material adhered to the substrate. Fragments 121 of the magnetic metallic material are separated by spaces 122 that extend in the plane of the layer. The fragments are arranged in a non-random pattern. The substrate 110 may comprise a flexible polymeric film or tape. According to some embodiments, the substrate is a layer of polyethylene terephthalate which may have a thickness of about 50 μm. The magnetic metallic material can be an annealed nanocrystalline magnetic metallic material. For example, the magnetic metallic material may comprise materials such as nanocrystalline Fe, Ni, Co, or alloys thereof. The magnetic metallic material may also comprise materials that enhance the formation and final size of these nanocrystals, such as Cu, Zr, Nb, and Hf The magnetic metallic material may further comprise materials that enhance the magnetic coupling between these nanocrystals, or the magnetic properties of the nanocrystals themselves, such as Si, and B. The magnetic material can have an average relative magnetic permeability greater than about 50 and an average electrical resistivity greater than 100 μΩ-cm, for example

FIG. 1C shows a close up of a portion 100a of the magnetic isolator 100. As depicted in the close-up portion 100a, the layer 120 of magnetic material has a thickness, t, which may be greater than 1 μm in many embodiments. Spaces 122 between the fragments 121 extend between the major surfaces 131, 132 of the layer 120 and have an average width, w, that is less than about 0.5 t, less than about 0.1 t, or even less than 0.05 t. A majority of the spaces 122 may extend substantially, e.g., more than 75% of the entire distance between the first major surface 131 and the second major surface 132 of the layer 120 along a thickness axis of the layer 120. In some implementations, majority of the spaces 122 extend substantially perpendicularly, e.g., deviating by less than about +/−10 degrees from perpendicular, through the thickness of the layer 120. The fragments can generally approximate a right prism being three dimensional and having two parallel bases that are the same shape and several rectangular faces depending upon the shape of the bases. The bases and rectangular faces intersect at about a 90 degree angle. According to some configurations, the spaces 122 are the result of cracking the layer 120 of magnetic material. The spaces 122 include crack artifacts that distinguish the cracks from other types of spaces, such as spaces formed through lithography or laser scribing. In contrast to a lithographic or laser scribed gap, cracks include observable artifacts on the side walls of the crack that can be used to identify the space as a crack. FIG. 1D shows a close-up cross sectional view of crack 122′ that separates fragments 121 of magnetic material. The left sidewall 122′l of the crack 122′ includes features 122a, 122b. The right sidewall 122-r of the crack 122′ features 122a′, 122b′ that are complementary to left sidewall features 122a, 122b. The features 122a′, 122b′ 122a, 122b can comprise small protrusions that fit within small recesses or other types of complementary features. Furthermore, cracks can be distinguished from spaces formed by processes involving chemical etching due to the lack of locations of overcutting or undercutting by the etching process; cracks can be distinguished from spaces formed by laser scribing or other processes that involve heat because of observable structural and/or material changes such as melting at the sidewall of the space due to heat exposure.

Fragments of the magnetic material having an elongated structure can exhibit magnetic shape anisotropy wherein the fragment has an easy axis of magnetization and an orthogonal hard axis of magnetization. According to some embodiments a majority of the fragments have an elongated shape that causes them to exhibit magnetic shape anisotropy along easy and orthogonal hard axes that lie generally in the plane of the layer.

As illustrated in the plan views of FIGS. 2 through 6, the spaces extend linearly in an x-y plane of the magnetic layer separating or at least partially separating the fragments from one another. In some configurations all or some of the spaces intersect, although the spaces need not intersect as illustrated at least by FIG. 5. The pattern of the fragments is observable in the plan views of FIGS. 2-6. The pattern of fragments is non-random and may be a non-repeating pattern as shown in FIGS. 2, 6, and 7. However, in many configurations, the pattern of the fragments is a pattern that repeats at regular intervals. When observed in plan view, the surfaces of the fragments form geometrical shapes, rectangles, squares, triangles, circles, etc., in the x-y plan of the magnetic layer. The crack spacing might be about 0.5 mm to about 2 mm. The surface area of the fragments may range from about 0.25 mm² to about 100 mm², for example, or greater than about t².

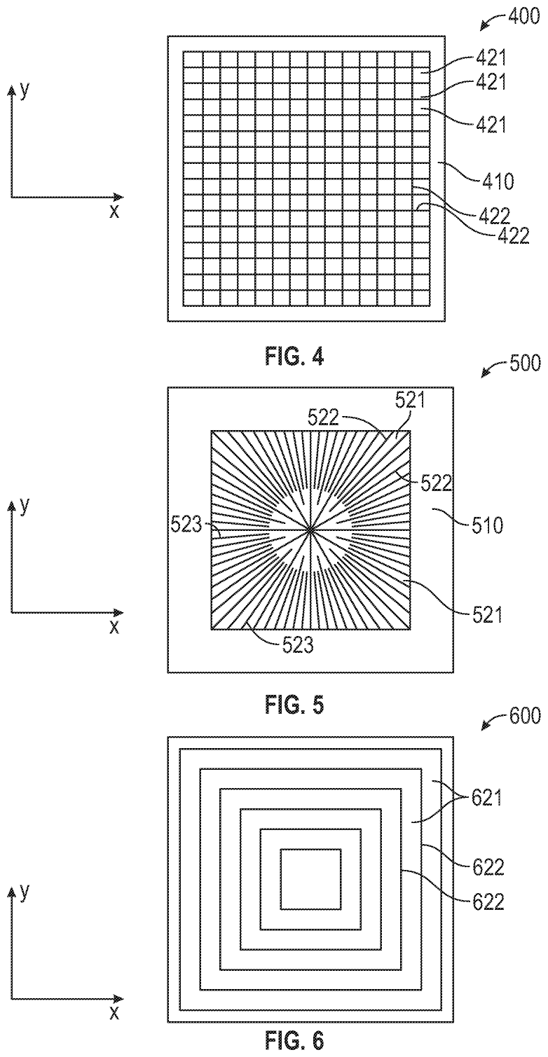

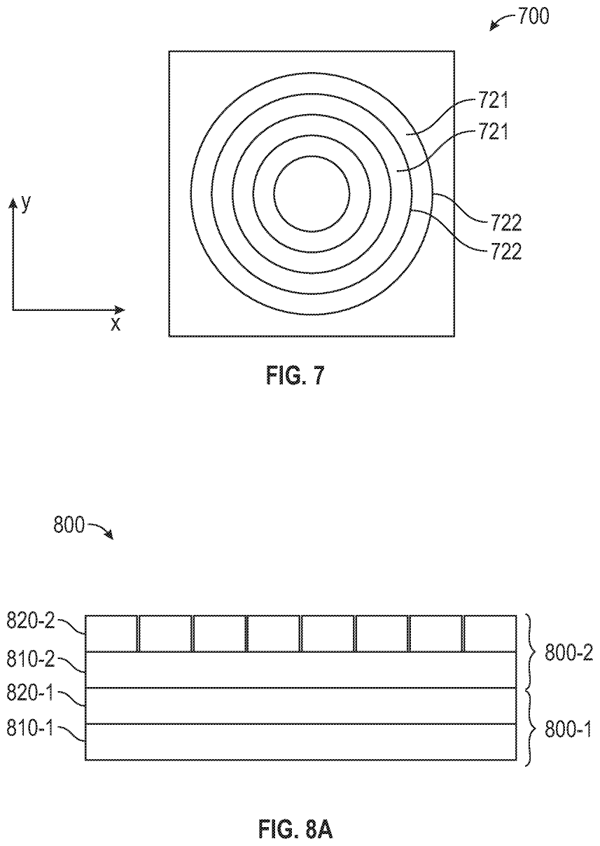

FIG. 2 is a plan view of a magnetic isolator 200 having fragments 221 separated by spaces 222 wherein the fragments 221 are arranged in a non-repeating chirp pattern. FIG. 3 is a plan view of a magnetic isolator 300 having fragments 321 separated by spaces 322. The surfaces of the fragments 321 of magnetic isolator 300 form substantially identical elongated rectangles arranged in a repeating pattern such that the elongated rectangles extend horizontally across the substrate 310 along the x direction in FIG. 3. FIG. 4 is a plan view of a magnetic isolator 400 having fragments 421 separated by spaces 422. The surfaces of the fragments 421 form squares arranged in a repeating pattern such that the squares form a two dimensional array extending in x and y directions across the substrate 410 in FIG. 4. FIG. 5 is a plan view of a magnetic isolator 500 having fragments 521 separated by spaces 522. The spaces 522 radiate from the center of the magnetic isolator 500 such that the surfaces of the fragments 521 form repeating triangles. Note that some of the spaces 523 of isolator 500 do not intersect with each other. In general, all, some, or none of the spaces of a magnetic isolator intersect with one another. FIG. 6 is a plan view of a magnetic isolator 600 having fragments 621 separated by spaces 622. The spaces form concentric squares. FIG. 7 is a plan view of a magnetic isolator 700 having fragments 721 separated by spaces 722. The spaces form concentric circles. FIGS. 6 and 7 are examples of isolators 600, 700 that comprise fragments 621, 721 arranged in a non-repeating pattern across the x-y plane of the magnetic isolator 600, 700. FIG. 7 provides one example of spaces 722 that extend nonlinearly across the x-y plane of the magnetic isolator 700.

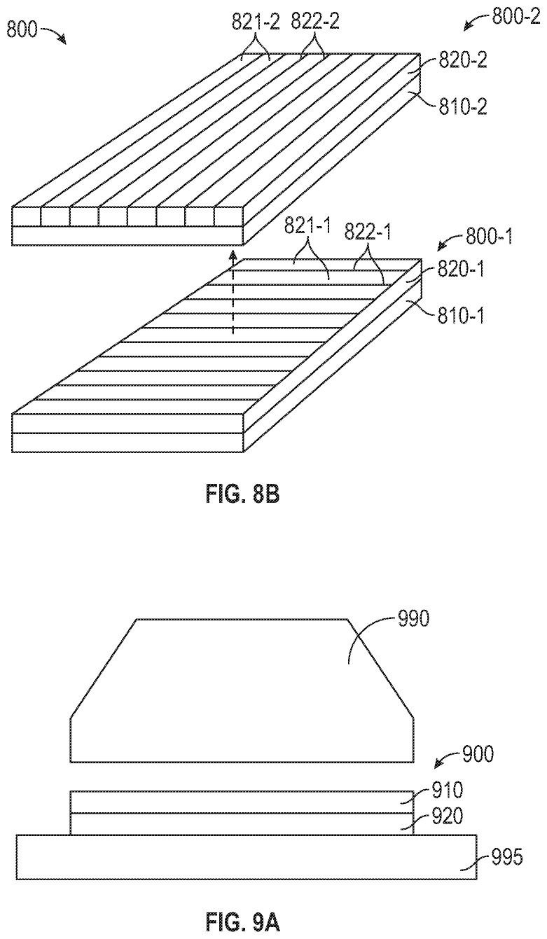

In some implementations, it may be useful to stack multiple magnetic isolators as shown in cross sectional view of FIG. 8A and the exploded view of FIG. 8B. FIGS. 8A and 8B illustrate an article 800 having first and second magnetic isolators 800-1, 800-2 where the second magnetic isolator 800-2 is stacked on the first magnetic isolator 800-1 in this embodiment. One or both of the magnetic isolators 800-1, 800-2 includes a substrate 810-1, 810-2 having a layer 820-1, 820-2 of fragmented magnetic metallic material adhered to the substrate 810-1, 810-2. Fragments 821-1, 821-2 of the magnetic metallic material are separated by spaces 822-1, 822-2 that extend in the plane of the layer 820-1, 820-2. The fragments 821-1, 821-2 are arranged in a non-random pattern. In some embodiments, at least some of all of the spaces extend linearly. In some embodiments, at least some of the spaces extend non-linearly.

In some configurations, the first and second isolators have patterns of fragments that are the same as in FIGS. 8A and 8B. Alternatively, the patterns of fragments of the first and second isolators may be different. In some embodiments, the patterns of the fragments of the first and second magnetic isolators are the same, but the patterns are rotated with respect to one another, e.g., rotated about 90 degrees, as in the embodiment depicted in FIGS. 8A and 8B. In some embodiments an adhesive layer can be arranged between the first and second magnetic isolators. In general, two or more single-layer magnetic isolators (including any of those as described above) may be stacked, optionally with thin adhesive layers in between. The stacked layers may be cracked in the same pattern, and aligned to one another. Or, they may have complementary patterns, resulting in a different overall magnetic anisotropy profile than any one layer by itself.

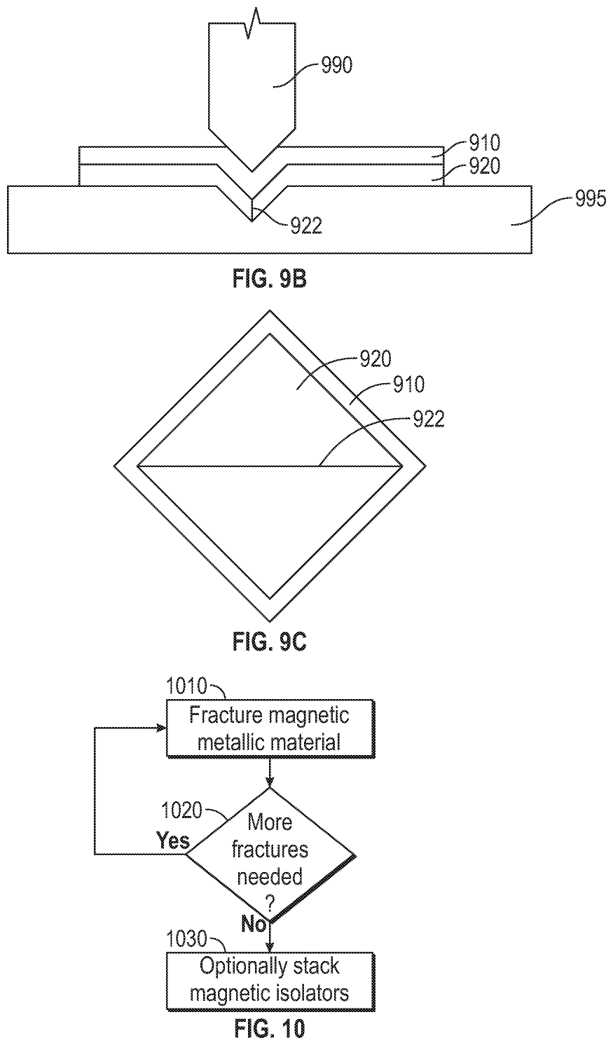

FIGS. 9A through 9C are diagrams that illustrate a process for making a magnetic isolator in accordance with embodiments discussed herein. Formation of an annealed unfragmented nanocrystalline magnetic metallic layer on a substrate may be accomplished using any known process. In some embodiments, the annealed unfragmented nanocrystalline magnetic metallic layer is optionally sandwiched between two layers of single-side adhesive tape. One layer of tape may be much more “stretchy” having a lower in-plane rigidity than the other layer of tape. The stretchiness of the tape is an aspect that allows the sandwiched structure to be compliant over the “cracking tool”. The tape that has higher in-plane rigidity serves to hold the unfragmented nanocrystalline magnetic metallic layer fragments together after fracture, thus serving as the substrate of the magnetic isolator. The spacing between fragments is presumed to affect overall resistivity and the demagnetization field between fragments. The stretchy tape may also have a low-tack adhesive, as the purpose of this tape is primarily to protect the nanocrystalline magnetic metallic layer through the cracking process.

FIG. 9A shows a side view of a cracking tool 990 poised over a magnetic isolator 900 comprising stack including an unfragmented nanocrystalline magnetic metallic layer 920 disposed on a substrate 910. FIG. 9B shows a front view of the cracking tool 990 in contact with the substrate 910 during the process of cracking the magnetic metallic layer 920. A protective layer of tape (not shown) may be disposed on the magnetic isolator 900, in direct contact with the magnetic metallic layer 920 as previously discussed. In one configuration, the cracking tool 990 may be a knife blade. The knife blade 990 may be just dull enough not to cut through the substrate 910. On the opposite side of the magnetic metallic layer from the cracking tool 990 is a compliant surface 995 (e.g. thin rubber), which causes the magnetic metallic layer 920 and substrate 910 to fold over the edge of the cracking tool 990 when force is applied. Optimally, the cracking tool 990 contacts the magnetic isolator along the full line of intended fracture at the same time. This is unlike a circular fracturing tool (a disk-shaped knife edge) rolling over the magnetic metallic layer, as this will only contact the nanocrystalline magnetic metallic layer at a point at any one time. The resulting fracture in the case of the rolling knife edge will be multiple fracture lines radiating out in all directions from the point of contact, whereas the desired fracture is a linear fracture 922 defined by the geometry and placement of the knife blade 990. FIG. 9C is a diagram illustrating the magnetic metallic layer 910 disposed on a substrate after the cracking tool 990 is used to make a single diagonal crack 922 across the magnetic metallic layer 920. FIG. 10 is a flow diagram that illustrates a process of making an article comprising one or more magnetic isolators in accordance with some embodiments. The process includes fracturing 1010 a layer of magnetic metallic material into fragments. The fracturing continues until 1020 the layer of magnetic metallic material is fractured into a non-random pattern of the fragments separated by spaces (fractures). The layer of the magnetic metallic material has a thickness, t, greater than 1 μm and the spaces separating the fragments having an average width of less than 0.5 t. According to some embodiments, the article may include multiple magnetic isolators. Each magnetic isolator is fractured as described above and the cracked isolators are stacked 1030.

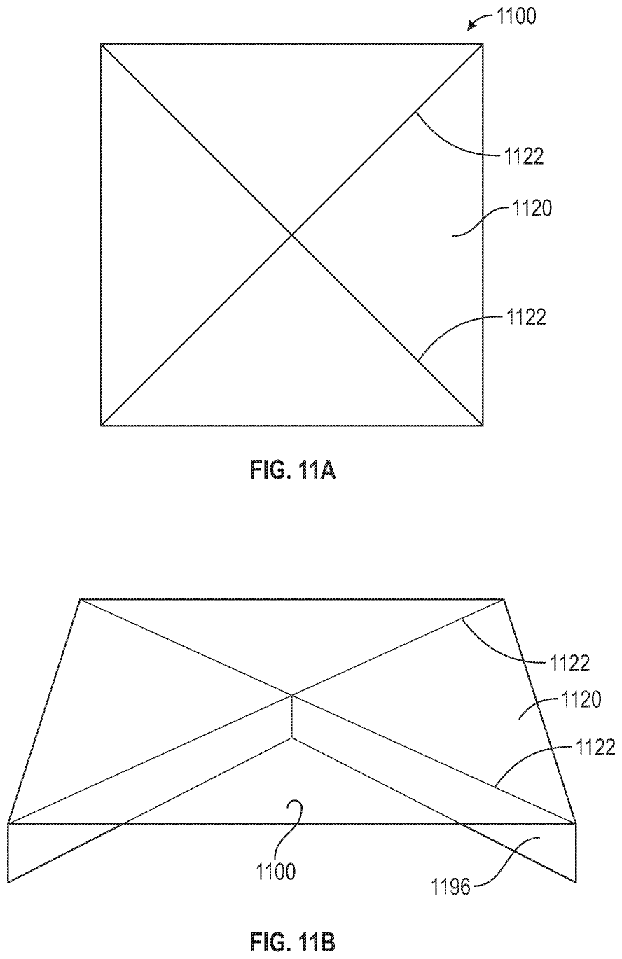

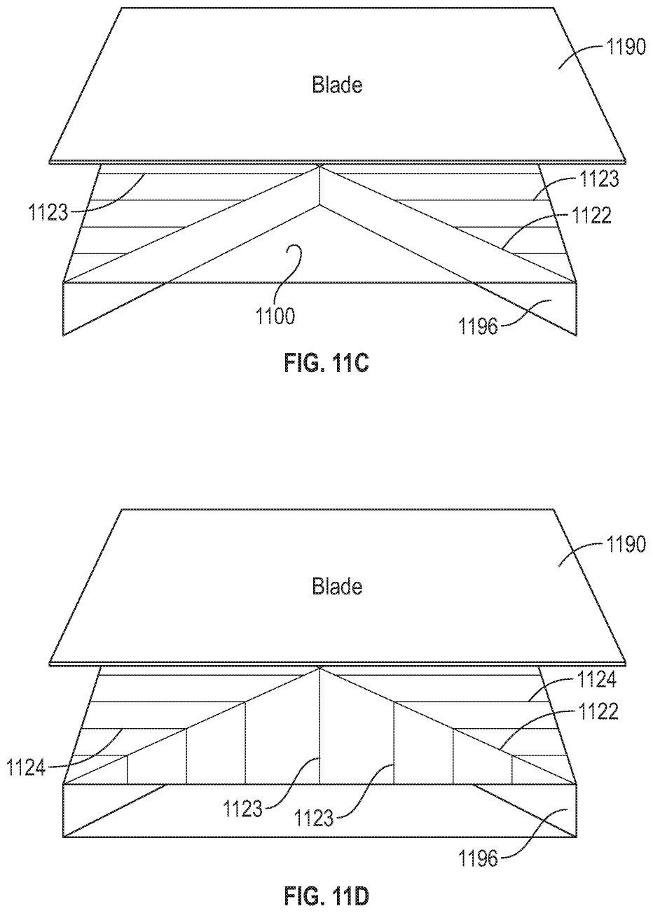

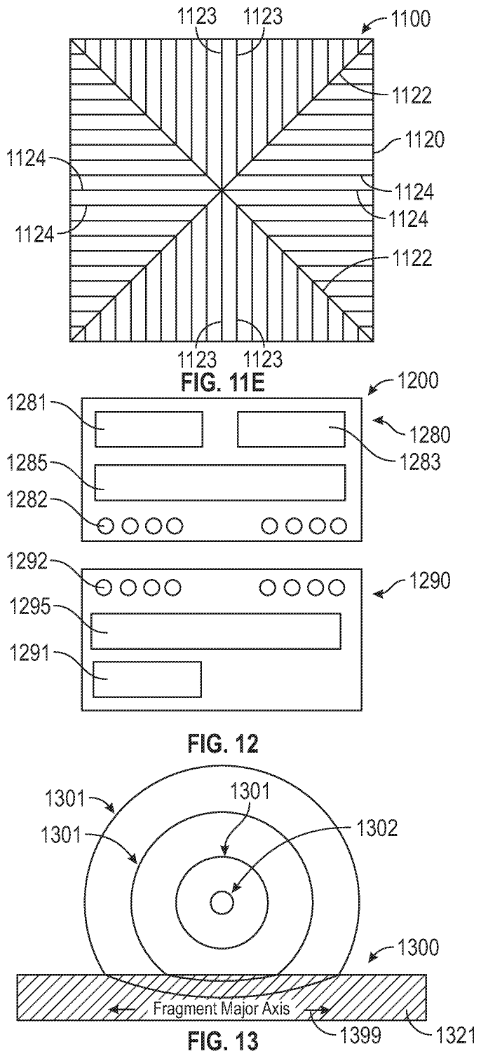

FIGS. 11A through 11E illustrate a process of cracking a magnetic metallic material to achieve a non-random pattern of fragments in accordance with some embodiments. With proper tooling, the illustrated process can be automated and controlled with arbitrary precision.

Annealed magnetic metallic film is adhered to a substrate, such as a 50 μm PET substrate. This stack is then cut into a square, e.g., about 50 mm on a side. It will be appreciated that other shapes are also possible. The magnetic metallic material 1120 is then blade-cracked along the two diagonals by placing the layer stack on a thin sheet of flexible material (e.g. silicone or rubber), and pressing a blade edge down with just enough force to cause the magnetic metallic material to fracture beneath, while not cutting through the PET. FIG. 11A is a plan view showing the layer stack 1100 comprising a magnetic metallic material 1120 with diagonal cracks 1122.

The layer stack 1100 is then placed on a platen 1196 of raised flexible material, which is shaped to match the two diagonal cracks, such that the cracks align with the edges of the raised platen 1196, as shown FIG. 11B. The sample is further cracked using a blade 1190 at the desired spacings as illustrated in FIG. 11C. The new cracks 1123 run substantially perpendicular to the sides of the layer stack. Only the magnetic metallic material 1120 which is backed by the raised platen 1196 cracks under the force of the blade 1190, and the diagonal cracks 1122 act as a boundary to terminate propagation of these cracks 1123. After completing all cracks in one direction, the layer stack 1100 is rotated 90 degrees, and the process is repeated to form another set of cracks 1124 as depicted in FIG. 11D. FIG. 11E is a plan view of the magnetic isolator 1100 including the cracked magnetic metallic layer 1120.

The process outlined above need not be piecemeal as described. For example, the process of cracking may be carried out on a continuous roll of taped NCR, with several sets of platens and blades set in a line, and at the proper orientation to form the desired cracked pattern. Then, from this roll, individual samples may be cut.

The magnetic isolator discussed herein can be used in various implementations including in wireless charging of batteries that power electronic devices, such as cellular telephones. Wireless charging transfers energy from a charger to a receiver by electromagnetic induction. The charger uses an induction coil to create an alternating electromagnetic field. The magnetic field generates a current in the receiver coil which is used to charge the battery. The magnetic isolator can be employed to shape the magnetic fields of the receiver and/or charger coils to increase energy transfer and/or to isolate any nearby lossy materials from the magnetic fields. FIG. 12 is a block diagram of a system 1200 that may incorporate one or more magnetic isolators as discussed herein to facilitate wireless battery charging or other processes. The system 1200 includes an electronic device 1280 comprising a battery 1281 that requires periodic charging and a charging device 1290 configured to wirelessly charge the battery 1281. The electronic device 1280 includes electronic circuitry 1283 such as circuitry needed to make and receive cellular telephone calls, etc. The battery 1281 supplies the energy for powering the electronic circuitry 1283.

The charging device 1290 includes an induction coil 1292 that can be energized to generate an electromagnetic field. When the electronic device 1280 is brought into close proximity to the induction coil 1292 the induction coil is inductively coupled to a receive coil 1282 of the electronic device 1280. The receive coil 1282 converts the electromagnetic field to a current that is used to charge the battery 1281.

One or both of the electronic device 1280 and the charging device 1290 may include a magnetic isolator 1285, 1295 as discussed herein arranged between the receive or transmitter coils 1282, 1292 and components 1281, 1283, 1291 of the device 1280, 1290. Components 1281, 1283, 1291 may be magnetically lossy when exposed to the electromagnetic field. The magnetic isolator 1285, 1295 can shape the magnetic fields of the receiver and/or charger coils to increase energy transfer and/or to isolate any nearby lossy materials from the magnetic fields and prevent electromagnetic interference (EMI) issues in both devices.

In currently available isolators, the resulting fragments are not intentionally elongated in any one direction, and so, have little or no magnetic shape anisotropy. In fact, in many applications of magnetic flux guiding materials, magnetic shape anisotropy is generally considered only to have negative consequences. In this case, the tradeoff between reducing eddy current loss, and maintaining high permeability is fixed.

In some embodiments, the magnetic metallic material is purposely cracked into fragments with a high length-to-width (aspect) ratio, so that the fragments maintain their high magnetic permeability along the major axis, while still appreciably reducing eddy current losses. When an induced magnetic field is aligned with the major axis of the fragment, the fragment is able to carry more of that magnetic flux. In this way, the tradeoff between permeability and conductivity can be made more favorable.

FIG. 13 is a cross sectional diagram of an antenna wire 1302 illustrating shaping of magnetic flux lines 1301 in the vicinity of the receive or transmit antenna coils 1302. The flux lines 1301 are affected by the magnetic metallic material fragments 1321 of the magnetic isolator 1300. In some embodiments, aligning the major axes 1399 of the fragments 1321 parallel to the magnetic flux lines 1301 as shown may be useful as discussed in more detail below. When the fragments 1321 are elongated and unbroken in a direction that is about parallel to the direction of the flux lines 1301, the magnetic permeability (capacity to carry magnetic flux) of the fragment 1321 remains high. In this configuration, the effectiveness of the magnetic isolator 1300 to reduce flux lines that enter lossy materials disposed below the isolator 1300 is enhanced.

The cracking technique discussed above enables the formation of elongated fragments of magnetic metallic material that have a high degree of magnetic anisotropy which can be oriented with respect to an antenna coil, thus increasing transfer efficiency. The magnetic anisotropy is provided in the form of magnetic shape anisotropy of the high-aspect-ratio fragments of the cracked magnetic metallic material. A majority of the fragments can be formed to exhibit magnetic shape anisotropy along easy axes and orthogonal hard axes that lie in a plane of the layer. According to some implementations, the magnetic permeability along the easy axes may be greater than about 1.3 times or even greater than about 5 times the magnetic permeability along the hard axis, for example.

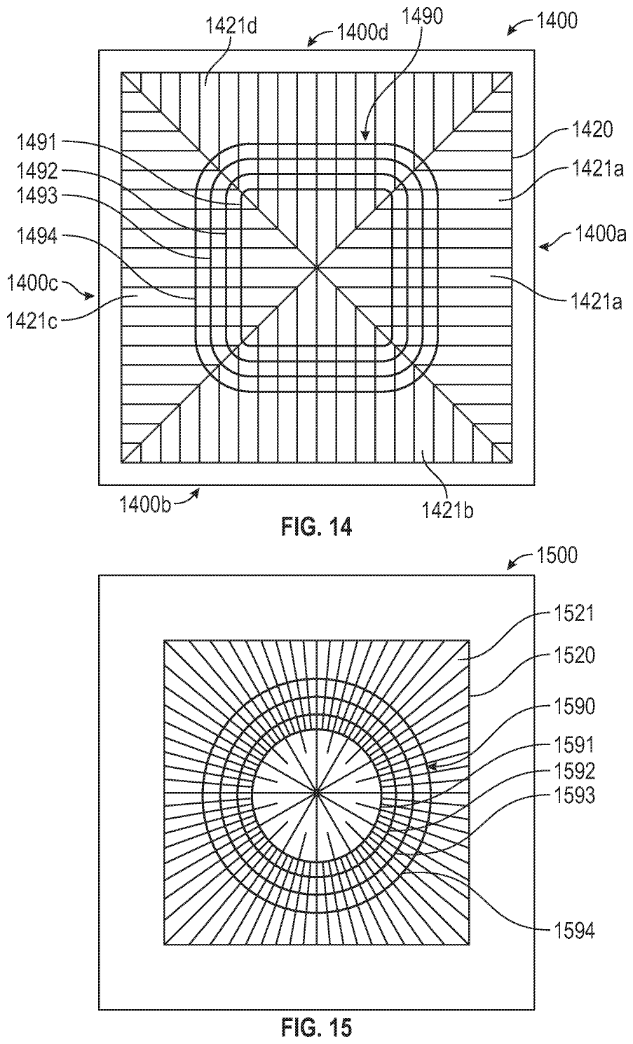

In some configurations of an electronic device or charging device, the coil antenna comprises at least one electrically conductive antenna segment. The fragments of the magnetic metallic material have magnetic shape anisotropy. The fragments are arranged such that a majority of a length of the antenna segment is substantially perpendicular to the easy (major) axes of the fragments. For example, more than 50% of the length of the antenna segment may be substantially perpendicular, e.g., 90 degrees +/−10 degrees to the easy axes. FIGS. 14 and 15 illustrate arrangements in which the orientation of the fragments of magnetic metallic material relative to the antenna coil takes advantage of the magnetic shape anisotropy of the fragments to enhance energy transfer from the coil.

FIG. 14 shows a plan view of a magnetic isolator 1400 comprising a magnetic metallic layer 1420 that is cracked into four triangular sections 1400a-b of polygonal fragments 1421. A majority of the fragments 1421 have an aspect ratio greater than 1 such that the length of the polygons is greater than their width. Thus, these fragments will exhibit magnetic shape anisotropy wherein the easy axes of magnetization lies along the major axes of the fragments 1421.

FIG. 14 also shows an outline of a coil 1490 arranged relative to the magnetic isolator 1400. In the configuration depicted in FIG. 14, the coil 1490 comprises multiple turns 1491, 1492, 1493, 1494 that form concentric rounded rectangles. Each side (top, bottom, left, right) of each rectangular coil turn 1491, 1492, 1493, 1494 is oriented so that the side is substantially perpendicular to the major axis of the fragments 1421a-d. For example, the major axes of polygons 1421a are substantially perpendicular to the right sides of rounded rectangles 1491-1494; the major axes of polygons 142 lb are substantially perpendicular to the bottom sides of rounded rectangles 1491-1494; the major axes of polygons 1421c are substantially perpendicular to the left sides of rounded rectangles 1491-1494; and the major axes of polygons 1421c are substantially perpendicular to the top sides of rounded rectangles 1491-1494. The magnetic flux lines that are present when the coil turns 1491, 1492, 1493, 1494 are energized form circular loops around the coil turns on a plane perpendicular to the axis of the coil. The plane formed by these flux loops are substantially parallel with the major axis of the fragments 1421a-d. The arrangement enhances energy transfer from the coil 1490.

FIG. 15 shows a plan view of a magnetic isolator 1500 comprising a magnetic metallic layer 1520 that has triangular or polygonal fragments 1521 that radiate output from the center of the magnetic isolator. A majority of the fragments 1521 have a length greater than their width. Thus, these fragments 1521 will exhibit magnetic shape anisotropy wherein the easy axes of magnetization lies along the length axes of the fragments 1521.

FIG. 15 also shows an outline of a coil 1590 arranged relative to the magnetic isolator 1500. In the configuration depicted in FIG. 15, the coil 1590 comprises multiple turns 1591, 1592, 1593, 1594 that form concentric circles. Each circular coil turn 1591, 1592, 1593, 1594 is oriented so that the coil turns are perpendicular to the length axis of the fragments 1521. The magnetic flux lines that are present when the coil turns 1591, 1592, 1593 are energized form circular loops around the coil turns on a plane perpendicular to the axis of the coil. The plane formed by these flux loops are substantially parallel with the major axis of the fragments 1521. The arrangement of the magnetic metallic material fragments with respect to the coil turns as depicted in FIGS. 14 and 15 enhances energy transfer from the coil.

Embodiments described herein include:
Item 1. An article comprising:

one or more magnetic isolators, each magnetic isolator comprising:
a substrate; and
a layer of fragmented magnetic metallic material adhered to the substrate, fragments of the magnetic metallic material separated by spaces and arranged in a non-random pattern, the layer of magnetic metallic material having a thickness, t, greater than 1 μm, and the spaces having an average width of less than 0.5 t.
Item 2. The article of item 1, wherein the magnetic metallic material has an average relative magnetic permeability greater than about 50.
Item 3. The article of any of items 1 through 2, wherein the magnetic metallic material has an average electrical resistivity greater than 100 μΩ-cm.
Item 4. The article of any of items 1 through 3 wherein the non-random pattern is a repeating pattern.
Item 5. The article of any of items 1 through 4, wherein a majority of the spaces extend substantially perpendicularly between major surfaces of the layer through the thickness of the layer.
Item 6. The article of items 1 through 5, wherein a majority of the spaces extend substantially an entire distance between a first major surface and a second major surface along a thickness axis of the layer.
Item 7. The article of any of items 1 through 6, wherein at least some of the spaces extend linearly in a plane of the layer.
Item 8. The article of any of items 1 through 7, wherein a majority of the fragments are right geometrical prisms.
Item 9. The article of any of items 1 through 8, wherein a majority of the fragments have a surface area greater than about t².
Item 10. The article of any of items 1 through 9, wherein the magnetic metallic material comprises a nanocrystalline magnetic metallic material.
Item 11. The article of any of items 1 through 10, wherein the magnetic metallic material comprises at least one of Fe, Ni, Co.
Item 12. The article of claim 1, wherein the one or more magnetic isolator units comprises multiple stacked magnetic isolator units.
Item 13. The article of any of items 1 through 12, wherein a majority of the fragments exhibit magnetic shape anisotropy along easy axes and orthogonal hard axes that lie in a plane of the layer.
Item 14. A device comprising:

a material that is magnetically lossy when exposed to an electromagnetic signal;

an antenna configured to transmit or receive the electromagnetic signal;

a magnetic isolator disposed between the antenna and the magnetically lossy material, each magnetic isolator comprising:
a substrate;
a layer of fragmented magnetic metallic material adhered to the substrate, the

layer of the magnetic metallic material having a thickness, t, greater than 1 μm; and
spaces that separate fragments of the magnetic metallic material, the spaces having an average width of less than 0.5 t and arranged in a non-random pattern.
Item 15. The device of item 14, wherein the magnetically lossy material comprises one or both of electronic circuitry and an energy storage device configured to supply power to the electronic circuitry.
Item 16. The device of any of items 14 through 15, wherein a majority of the fragments exhibit magnetic shape anisotropy along easy axes and orthogonal hard axes that lie in a plane of the layer.
Item 17. The device of any of items 14 through 16, wherein:

the non-random pattern repeats at regular intervals; and

a majority of the fragments are right geometrical prisms.
Item 18. A method of making a magnetic isolator comprising a stack that includes a layer of magnetic metallic material disposed on a substrate, the method comprising fracturing the magnetic metallic material into fragments arranged in a non-random pattern with spaces separating the fragments, the layer of the magnetic metallic material having a thickness, t, greater than 1 μm and the spaces separating the fragments having an average width of less than 0.5 t.
Item 19. The method of item 18, wherein fracturing the magnetic metallic material comprises repeatedly bringing an edge into contact with the stack and applying pressure to the layer through the edge until the magnetic metallic material fractures to form the fragments arranged in the non-random pattern.
Item 20. The method of any of items 18 through 19, further comprising:

making one or more additional magnetic isolators; and

stacking the magnetic isolator and the additional magnetic isolators.
Item 21. An article, comprising:

one or more magnetic isolators, each magnetic isolator comprising:
a substrate; and
at least one layer of fragmented magnetic metallic material adhered to the substrate, fragments of the magnetic metallic material separated by spaces, a majority of the fragments exhibiting magnetic shape anisotropy along easy axes and orthogonal hard axes that lie in a plane of the layer.
Item 22. The article of item 21, wherein magnetic permeability along the easy axes is at least greater than 1.3 times magnetic permeability along the hard axis.
Item 23. The article of any of items 21 through 22, wherein:

the layer has a thickness, t, greater than 1 μm; and

the spaces have a width of less than 0.5 t.
Item 24. The article of any of items 21 through 23 wherein the fragments are arranged in a non-random pattern.
Item 25. The article of item 24, wherein the non-random pattern is a repeating pattern.
Item 26. The article of any of items 21 through 25, wherein major axes of the fragments correspond to the easy axes and extend from an interior region of the layer toward an edge region of the layer.
Item 27. The article of any of items 21 through 26, wherein a majority of the fragments are rectangular or triangular right geometrical prisms.
Item 28. The article of any of items 21 through 27, wherein the magnetic isolator comprises multiple stacked magnetic isolators.
Item 29. The article of item of 28, wherein the multiple stacked magnetic isolator units comprise:

a first magnetic isolator unit with a first layer of fragmented magnetic metallic material, fragments of the first layer arranged in a first pattern; and

a second magnetic isolator unit with a second layer of fragmented magnetic metallic material, fragments of the second layer arranged in a second pattern different from the first pattern.
Item 30. The article of item 28, wherein the fragments of each of the multiple stacked magnetic isolators are arranged in the same pattern.
Item 31. The article of item 30, wherein the pattern of one of the magnetic isolators is arranged at an angle to the pattern of fragments of another of the magnetic isolators.
Item 32. A device comprising:

one or more magnetic isolators, each magnetic isolator comprising:
a substrate; and
at least one layer of fragmented magnetic metallic material adhered to the substrate, fragments of the magnetic metallic material separated by spaces, a majority of the fragments exhibiting magnetic shape anisotropy respectively along easy axes and orthogonal hard axes of the fragments, the easy and hard axes lying in a plane of the layer; and

an antenna comprising at least one electrically conductive antenna segment, wherein a majority of a length of the antenna segment is arranged to be substantially perpendicular to the easy axes of one or more fragments exhibiting magnetic shape anisotropy.
Item 33. The device of item 32, wherein magnetic permeability along the easy axes is greater than about 1.3 times the magnetic permeability along the hard axes.
Item 34. The device of any of items 32 through 33, wherein:

the layer has a thickness, t, greater than 1 μm; and

the spaces have a width of less than 0.5 t.
Item 35. The device of any of items 32 through 34, wherein the fragments are arranged in a non-random pattern.
Item 36. The device of any of items 32 through 35, wherein the antenna comprises multiple antenna segments and each antenna segment is one turn of a planar coil.
Item 37. The device of item 36, wherein:

the multiple antenna segments are concentric rounded rectangles; and

the fragments are arranged in a pattern comprising four triangular regions of a rectangle bisected by two diagonals, wherein the easy axes of fragments in adjacent triangular regions are substantially perpendicular to one another.
Item 38. The device of item 36, wherein:

the multiple antenna segments are circular; and

the fragments are arranged in a radial pattern.
Item 39. The device of item 36, wherein:

the magnetic isolator comprises multiple magnetic isolator units including at least first and second magnetic isolators; and

a first portion of the antenna segment is arranged to be substantially perpendicular to easy axes of fragments of the first magnetic isolator; and

a second portion of the antenna segment is arranged to be substantially perpendicular to easy axes of fragments of the second magnetic isolator.
Item 40. The device of any of items 32 through 39, further comprising:

electronic circuitry; and

an energy storage device configured to supply power to the electronic circuitry, wherein the magnetic isolator is disposed between the receiver antenna and one or both of the electronic circuitry and the energy storage device.
Item 41. A method of making a magnetic isolator comprising a stack that includes a magnetic metallic material disposed on a substrate, the method comprising fracturing the magnetic metallic material disposed on a substrate into fragments with spaces separating the fragments, a majority of the fragments exhibiting magnetic shape anisotropy along an easy axis and an orthogonal hard axis, the easy and hard axes lying in a plane of the layer.
Item 42. The method of item 41, wherein fracturing the magnetic metallic material comprises fracturing the layer of magnetic metallic material into fragments arranged in a non-random pattern.
Item 43. The method of any of items 41 through 42, further comprising:

making one or more additional magnetic isolators; and

stacking the magnetic isolator and the additional magnetic isolator.

### EXAMPLES

### Example 1

For this demonstration, three samples of magnetic metallic nanocrystalline ribbon (NCR) were prepared. The NCR was prepared by annealing Vitroperm VP800 melt-spun ribbon (obtained from VACUUMSCHMELZE) at a temperature between 500 C and 600 C in nitrogen. Adhesive tape was applied to the NCR samples, which were then cracked with orthogonal crack lines having a spacing of 1 mm, 1.5 mm, and 2 mm. For permeability measurements, the taped and cracked samples were glued to 10 mil thick FR4 (epoxy-impregnated fiberglass) board, and cut into toroids with an inner and outer diameter of 6 mm and 18 mm, respectively. For this example, the cracking was done “by hand” so the spacing between crack lines is approximate.

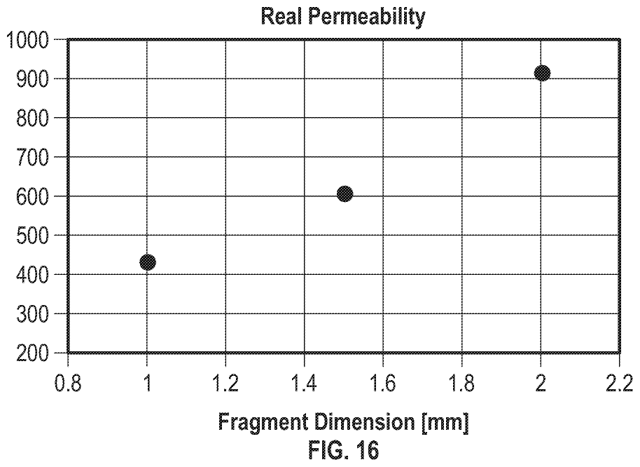

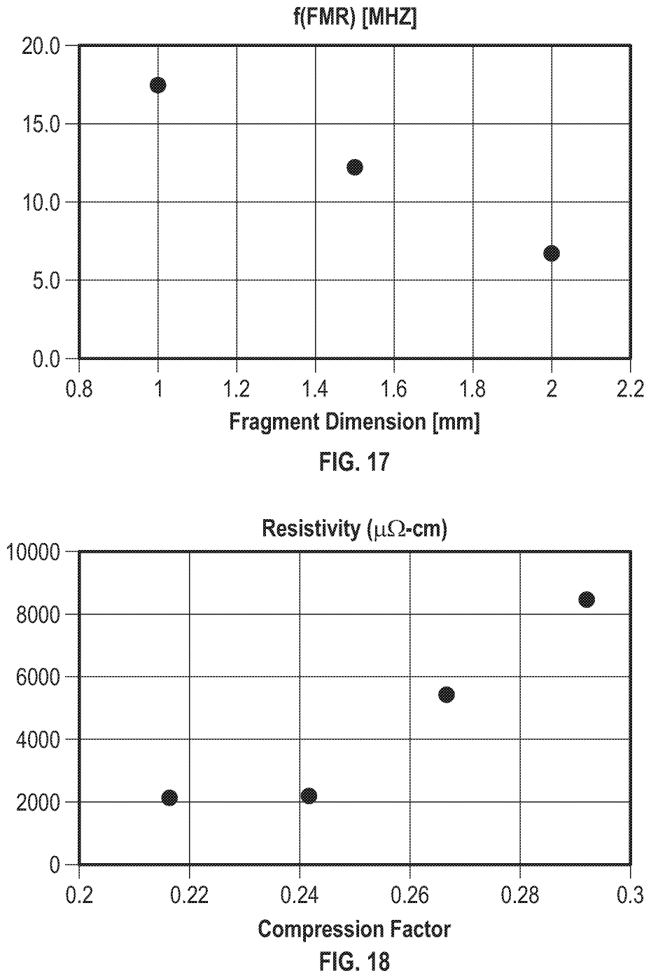

Permeability and ferromagnetic resonance f(FMR) were obtained from impedance measurements averaged over 4 samples each using an Agilent Technologies Impedance Analyzer (E4990A) with a Keysight Terminal Adapter (42942A) and coaxial test fixture (16454A). Values (averaged over 4 samples each) of real permeability (in the range of 10 kHz to 100 kHz) and f(FMR) as a function of fragment dimension are shown in FIG. 16 and FIG. 17, respectively. FIGS. 16 and 17 indicate that real permeability increases and f(FMR) decreases with fragment dimension.

### Example 2

Resistivity measurements, using a 4-point probe measurement system, were performed on a set of samples which were prepared in a somewhat different manner. In these samples, cracking was performed by compressing the taped NCR sample over a wire mesh. Although the fragments size is not known exactly in these samples, this experiment indicates that the fragment size is controlled by the amount of compressing force, or Compression Factor. As the compressing force increases, the fragment size decreases, and resistivity increases. FIG. 18 is a graph showing resistivity values (averaged over 4 samples each) for mesh-cracked NCR. For this method of cracking, fragment size monotonically decreases with Compression Factor in the range of Compression Factors used here.

### Example 3

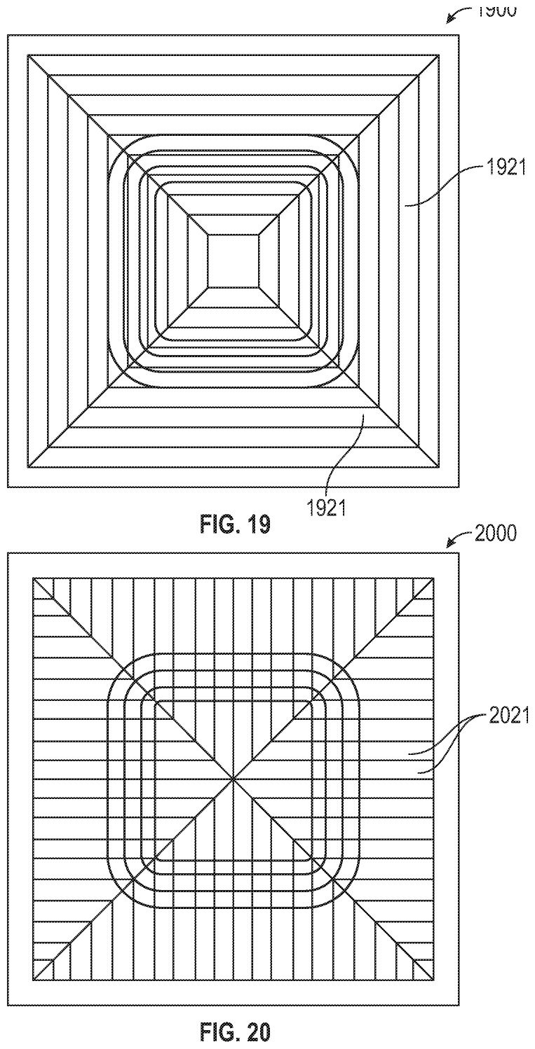

The relationship between power transfer and orientation of the coils with respect to the easy axis of fragments having magnetic shape anisotropy was investigated. Two samples were prepared by the general technique discussed with reference to FIGS. 11A through 11E to show the effect of intentional alignment and misalignment of the major axis of fragments. One sample 1900 was made with the major axis of fragments 1921 parallel to the outer edges of the square sheet of isolator material as illustrated in FIG. 19, and the other sample 2000 was made with the major axis of the fragments 2031 normal to the outer edges as shown in FIG. 20. In both samples, the spacing between cracks was nominally 1 mm. The isolator samples shown in FIGS. 19 and 20 were used in power transfer efficiency measurements. In the design shown in FIG. 20, the fragments 2021 are aligned with magnetic field induced by the coil 2090. In the design shown in FIG. 19, the fragments 1921 are intentionally misaligned with the magnetic field induced by the coil 1990.

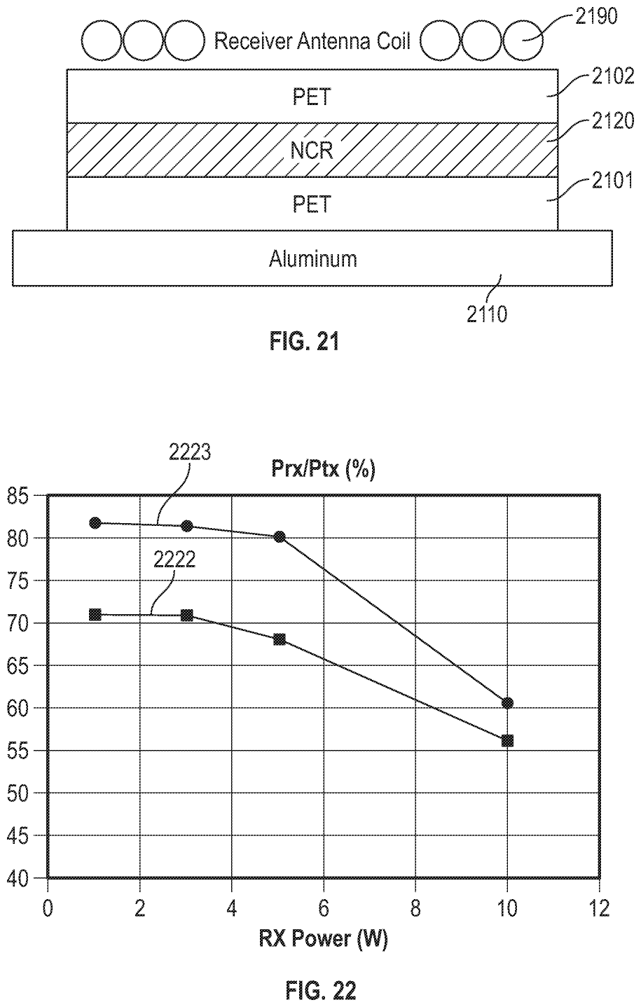

The magnetic isolator samples were placed in a stack, as shown in the FIG. 21. The fragmented NCR 2120 was sandwiched between two layers 2101, 2102 of 50 μm Polyethylene terephthalate (PET), and held in place by adhesive on both sides. An aluminum plate 2110 was placed underneath, to mimic the lossy materials found in devices using such wireless charging coils (e.g. phone batteries, electronic circuit boards, etc.), and on top, the receiver antenna coil. During the measurement, the transmitter coil (not shown in FIG. 21) is placed opposite the receiver coil 2190 at a fixed distance.

Power transfer efficiency, which is the ratio of power received by an antenna coil (receiver), relative to the power transmitted by another coil (transmitter), was measured for these two samples. FIG. 22 provides graphs of the power transfer efficiency (power received/power transmitted (Prx/Ptx)) with respect to the received power, RX, for sample 1900 (graph 2222) and for sample 2000 (graph 2223). The graphs 2222, 2223 provided in FIG. 22, indicate that the isolator with aligned fragments (isolator 2000 shown in FIG. 20) performs significantly better than the isolator with misaligned fragments (isolator 1900 shown in FIG. 19).

### Example 4

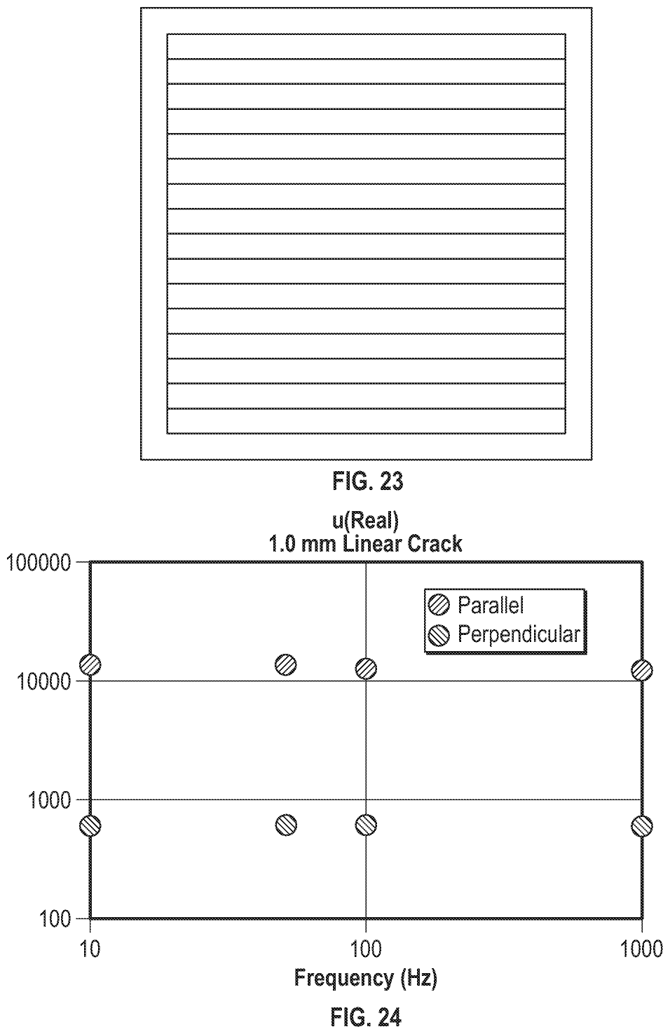

Another magnetic isolator sample was prepared with linear, or one-dimensional, cracking shown in FIG. 23 for the purpose of permeability measurement. The sample was made with spacing between cracks of nominally 1.0 mm. The permeability, μ(real) of this sample was measured parallel to the cracks, and perpendicular to the cracks, at a number of frequencies ranging from 10 to 1000 Hz. The results are shown in FIG. 24. These permeability values, measured at low frequency and low excitation, may be taken as the initial permeability of the sample. The ratio between the parallel and perpendicular values is a measure of the degree of anisotropy of the fragments.

Unless otherwise indicated, all numbers expressing feature sizes, amounts, and physical properties used in the specification and claims are to be understood as being modified in all instances by the term “about.” Accordingly, unless indicated to the contrary, the numerical parameters set forth in the foregoing specification and attached claims are approximations that can vary depending upon the desired properties sought to be obtained by those skilled in the art utilizing the teachings disclosed herein. The use of numerical ranges by endpoints includes all numbers within that range (e.g. 1 to 5 includes 1, 1.5, 2, 2.75, 3, 3.80, 4, and 5) and any range within that range.

Various modifications and alterations of the embodiments discussed above will be apparent to those skilled in the art, and it should be understood that this disclosure is not limited to the illustrative embodiments set forth herein. The reader should assume that features of one disclosed embodiment can also be applied to all other disclosed embodiments unless otherwise indicated. It should also be understood that all U.S. patents, patent applications, patent application publications, and other patent and non-patent documents referred to herein are incorporated by reference, to the extent they do not contradict the foregoing disclosure.

1. An article comprising:
one or more magnetic isolators, each magnetic isolator comprising:
substrate; and
a layer of fragmented magnetic metallic material adhered to the substrate, fragments of the magnetic metallic material separated by spaces and arranged in a non-random pattern, the layer of fragmented magnetic metallic material having a thickness, t, greater than one micrometer and the spaces having an average width of less than 0.5 t.

2. The magnetic isolator of claim 1, wherein the magnetic metallic material has an average relative magnetic permeability greater than about 50.

3. The article of claim 1, wherein a majority of the spaces extend substantially perpendicularly between major surfaces of the layer through the thickness of the layer.

4. The article of claim 1, wherein a majority of the spaces extend substantially an entire distance between a first major surface of the layer and a second major surface of the layer along a thickness axis of the layer.

5. The article of claim 1, wherein a majority of the fragments have a surface area greater than about t².

6. The article of claim 1, wherein the magnetic metallic material comprises a nanocrystalline magnetic metallic material.

7. The article of claim 1, wherein the magnetic metallic material is a nanocrystalline material comprising at least one of Fe, Ni, Co or alloys thereof.

8. The article of claim 1, wherein the one or more magnetic isolators comprises multiple stacked magnetic isolators.

9. The article of claim 1, wherein a majority of the fragments exhibit magnetic shape anisotropy along easy axes and orthogonal hard axes that lie in a plane of the layer.

10. A device comprising:
a material that is magnetically lossy when exposed to an electromagnetic signal;
an antenna configured to transmit or receive the electromagnetic signal;
a magnetic isolator disposed between the antenna and the magnetically lossy material, each magnetic isolator comprising:
a substrate;
a layer of fragmented magnetic metallic material adhered to the substrate, the layer of the magnetic metallic material having a thickness, t, greater than one micrometer; and
spaces that separate fragments of the magnetic metallic material, the spaces having an average width of less than 0.5 t and arranged in a non-random pattern.

11. The device of claim 10, wherein a majority of the fragments exhibit magnetic shape anisotropy along easy axes and orthogonal hard axes that lie in a plane of the layer.

12. The device of claim 11, wherein the antenna comprises at least one electrically conductive antenna segment and a majority of a length of the antenna segment is arranged to be substantially perpendicular to the easy axes of one or more fragments exhibiting magnetic shape anisotropy.

13. A method of making a magnetic isolator comprising a stack that includes a layer of magnetic metallic material disposed on a substrate, the method comprising fracturing the layer of magnetic metallic material into fragments arranged in a non-random pattern with spaces separating the fragments, the layer of the magnetic metallic material having a thickness, t, greater than one micrometer and the spaces separating the fragments having an average width of less than 0.5 t.

14. The method of claim 13, wherein fracturing the magnetic metallic material comprises repeatedly bringing an edge into contact with the stack and applying pressure to the layer through the edge until the magnetic metallic material fractures to form the fragments arranged in the non-random pattern.
